(19) United States
(12) Patent Application Publication
(10) Pub. No.: US 2013/0106875 A1
(43) Pub. Date: May 2, 2013

(54) METHOD OF IMPROVING THIN-FILM ENCAPSULATION FOR AN ELECTROMECHANICAL SYSTEMS ASSEMBLY

(71) Applicants: Rihui HE, San Jose, CA (US); Ana Rangelova LONDERGAN, Santa Clara, CA (US); Evgeni Petrovich GOUSEV, Saratoga, CA (US)

(72) Inventors: Rihui HE, San Jose, CA (US); Ana Rangelova LONDERGAN, Santa Clara, CA (US); Evgeni Petrovich GOUSEV, Saratoga, CA (US)

(73) Assignee: QUALCOMM MEMS TECHNOLOGIES, INC., San Diego, CA (US)

(21) Appl. No.: 13/287,801

(22) Filed: Nov. 2, 2011

(51) Int. Cl. G06F 13/14; G02B 26/00; H05K 3/00

(52) U.S. Cl. 345/520; 216/17; 359/290

(57) ABSTRACT

This disclosure provides systems, methods, and apparatus for fabricating electromechanical systems devices. In one aspect, a method of sealing an electromechanical systems device includes etching a sacrificial layer. The sacrificial layer is formed between a surface of a substrate and a shell layer and is etched through etch holes in the shell layer formed over the electromechanical systems device. The etch holes in the shell layer have a diameter greater than about one micron. The shell layer is then treated. A seal layer is deposited on the treated shell layer. The seal layer hermetically seals the electromechanical systems device.

### CROSS-REFERENCE TO RELATED APPLICATIONS

This application is related to U.S. patent application Ser. No. 12/976,647, titled “METHOD OF FABRICATION AND RESULTANT ENCAPSULTED ELECTROMECHANICAL DEVICE,” filed Dec. 22, 2010, which is herein incorporated by reference.

### TECHNICAL FIELD

This disclosure relates generally to electromechanical systems devices and more particularly to fabrication methods for electromechanical systems devices.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

An EMS device may be packaged to protect it from the environment and from operational hazards, such as mechanical shock. One way of packaging an EMS device to protect it from the environment can include various encapsulation techniques, including macro-encapsulation and thin-film encapsulation. A thin-film encapsulation process can involve depositing one or more thin film layers over the EMS device.

### SUMMARY

The systems, methods and devices of the disclosure each have several innovative aspects, no single one of which is solely responsible for the desirable attributes disclosed herein.

One innovative aspect of the subject matter described in this disclosure can be implemented in a method of sealing an electromechanical systems device. The method can include etching a sacrificial layer that is between a surface of a substrate and a shell layer formed over the electromechanical systems device. The sacrificial layer can be etched through etch holes in the shell layer. In some implementations, the etch holes can have a diameter greater than about 1 micron. After etching the sacrificial layer, the shell layer can be treated, with a seal layer then deposited on the treated shell layer. The seal layer can hermetically seal the electromechanical systems device.

In some implementations, etching the sacrificial layer can form a release passage connected to an etch hole. Depositing the seal layer may block the release passage. In some implementations, depositing the seal layer may include depositing a layer of aluminum oxide and depositing a layer of silicon oxynitride.

One innovative aspect of the subject matter described in this disclosure can be implemented in a method of sealing an electromechanical systems device. The method can include providing a substrate having an electromechanical systems device on a surface of the substrate. The substrate can also include a shell layer at least partially enclosing the electromechanical systems device. In some implementations, the shell layer can be substantially nonporous and include an etch hole. A sacrificial layer can then be etched from the substrate though the etch hole. Etching the sacrificial layer can form a release passage connected to the etch hole. In some implementation, a release passage can have a height of less than about 1 micron and a width of greater than about 1 micron. After etching the sacrificial layer, an adhesion improvement layer can be deposited on the shell layer. A seal layer can then be deposited on the shell layer. The seal layer can block a release passage and hermetically seal the electromechanical systems device.

In some implementations, the adhesion improvement layer may include at least a monolayer of aluminum oxide.

One innovative aspect of the subject matter described in this disclosure can be implemented in an apparatus including an electromechanical systems device formed on a substrate. The apparatus may further include a supporting means including a sealed etch hole and a sealing means for hermetically sealing the electromechanical systems device. The sealing means may be over the supporting means. The sealing means also may seal the etch hole with a portion of the sealing means blocking an opening of a release passage connected to the etch hole. In some implementations, the supporting means may be a shell layer and the sealing means may be a seal layer.

One innovative aspect of the subject matter described in this disclosure can be implemented in an apparatus including an electromechanical systems device formed on a substrate. A shell layer can at least partially enclose the electromechanical systems device between the shell layer and the substrate. The shell layer can include a sealed etch hole. In some implementations, a seal layer over the shell layer can hermetically seal the etch hole in the shell layer. A portion of the seal layer can block an opening of a release passage connected to the etch hole. In some implementations, the seal layer may include a layer of silicon oxynitride and a layer of aluminum oxide overlying the layer of silicon oxynitride.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a flow diagram illustrating an implementation of a manufacturing process for an EMS assembly.

FIGS. 10A-10D show examples of cross-sectional schematic illustrations of various stages in a method of fabricating an EMS assembly.

FIGS. 11A and 11B show examples of schematic illustrations of an EMS assembly.

FIG. 12 shows an example of a flow diagram illustrating a manufacturing process for an EMS assembly.

FIGS. 13A and 13B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to EMS devices and methods of their fabrication. In some implementations, an EMS device may be packaged with a thin-film encapsulation process. The thin film encapsulation process may involve treatments and/or processes that aid in making the thin-film encapsulation materials hermetic.

For example, in some implementations described herein to fabricate an EMS device, a substrate with an EMS device on the surface of the substrate is provided. A shell layer may be formed over the electromechanical systems device and on a sacrificial layer. The sacrificial layer may be etched through etch holes in the shell layer. The shell may be treated. A seal layer may be deposited on the treated shell layer, with the seal layer hermetically sealing the electromechanical systems device.

Particular implementations of the subject matter described in this disclosure can be implemented to realize one or more of the following potential advantages. Implementations of the methods may be used in a thin-film encapsulation process to provide a hermetic seal or to improve a non-hermetic seal. A hermetic seal may improve the performance of an EMS device by protecting it from components in the atmosphere, including water vapor, which may cause stiction. Stiction (i.e., static friction) may cause surfaces in the EMS device to adhere to one another and may result in failure of the EMS device.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

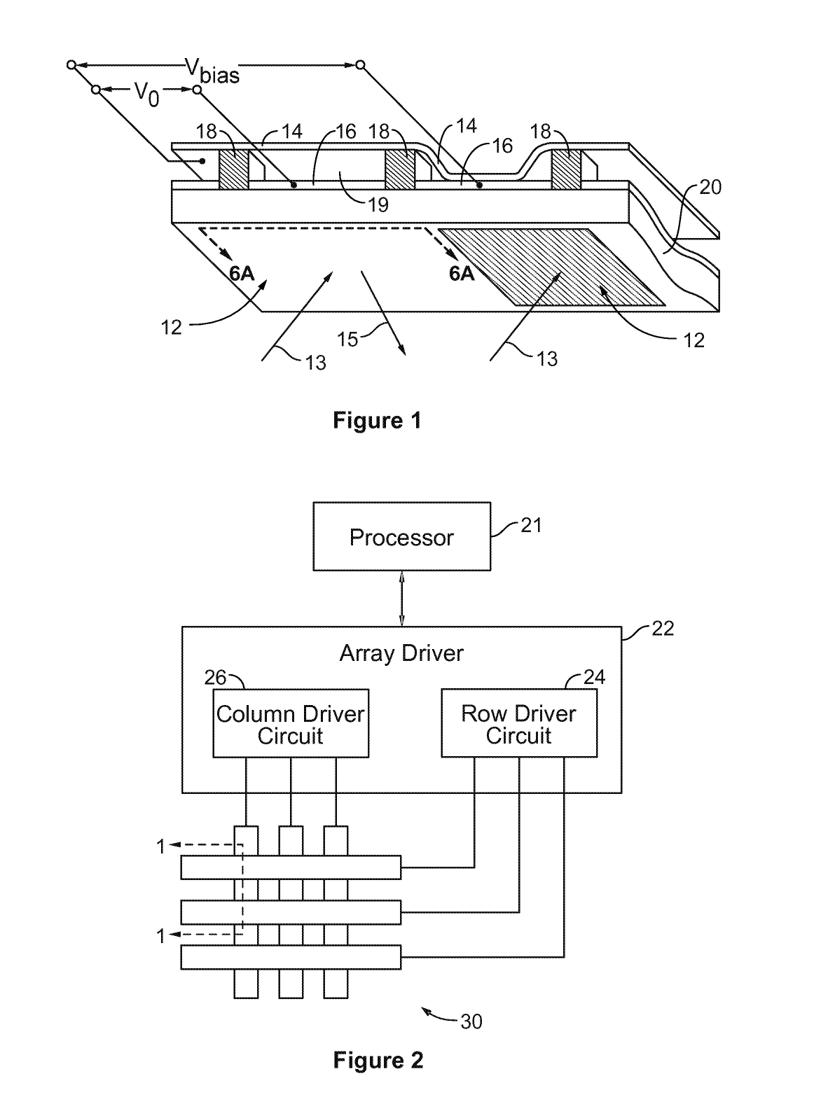

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (e.g., of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

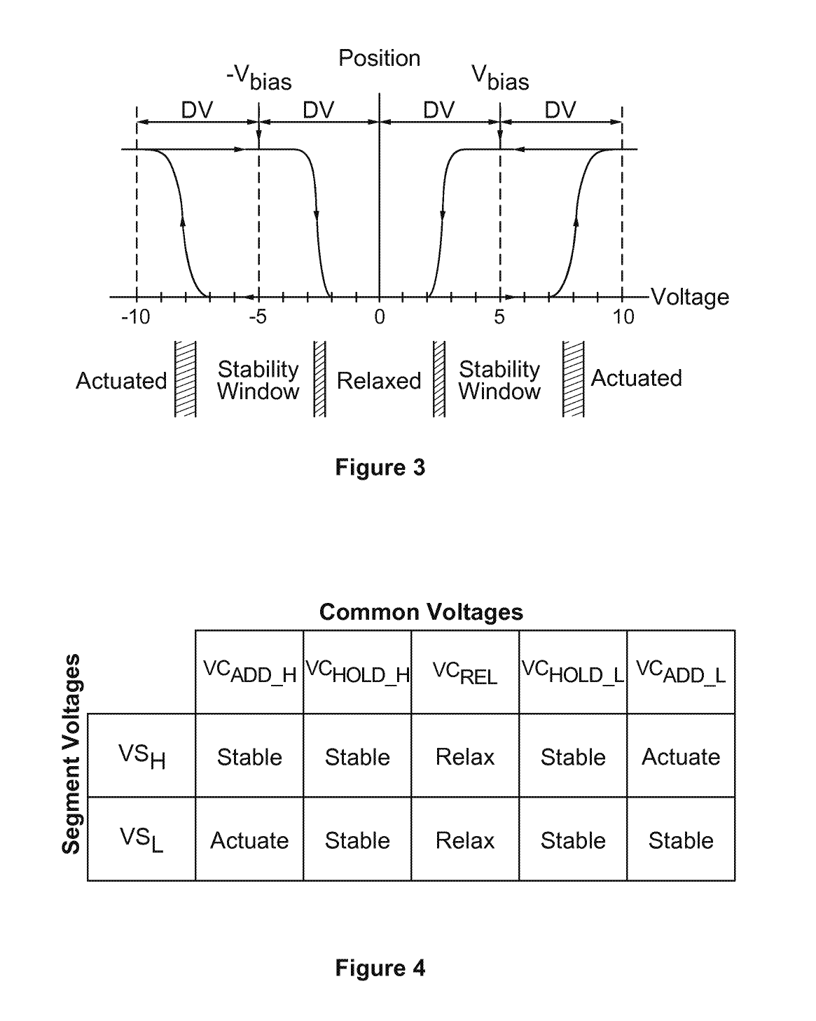

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

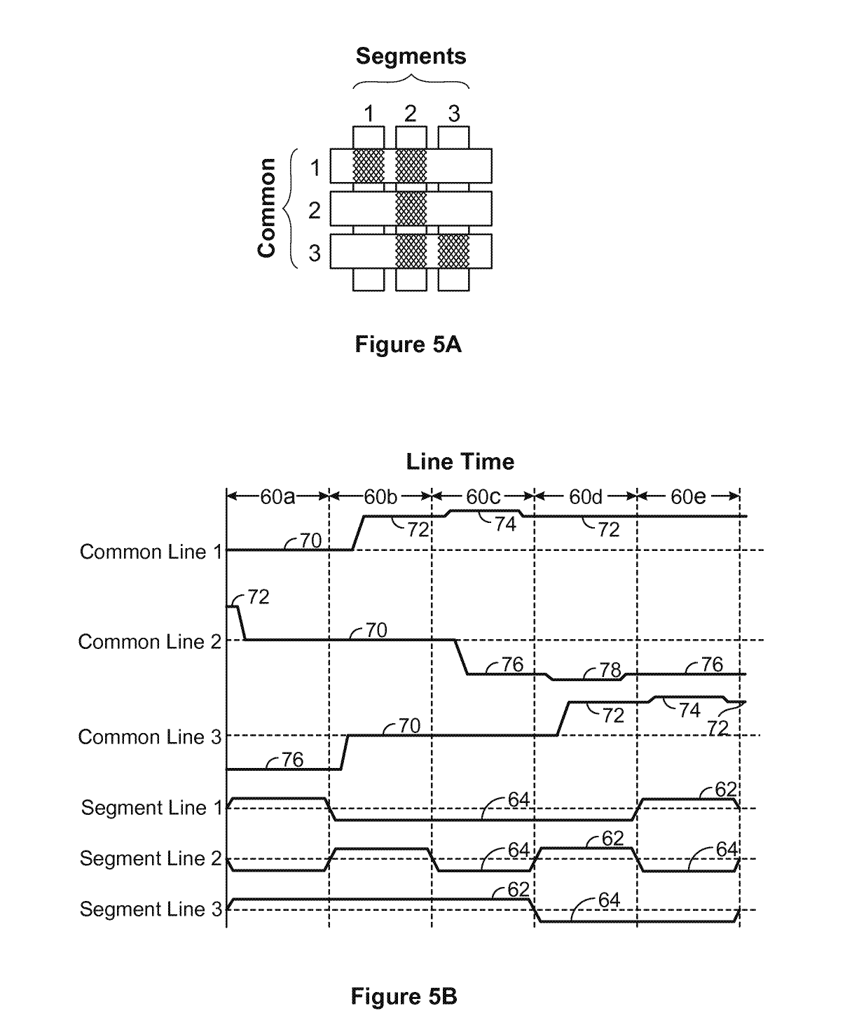

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

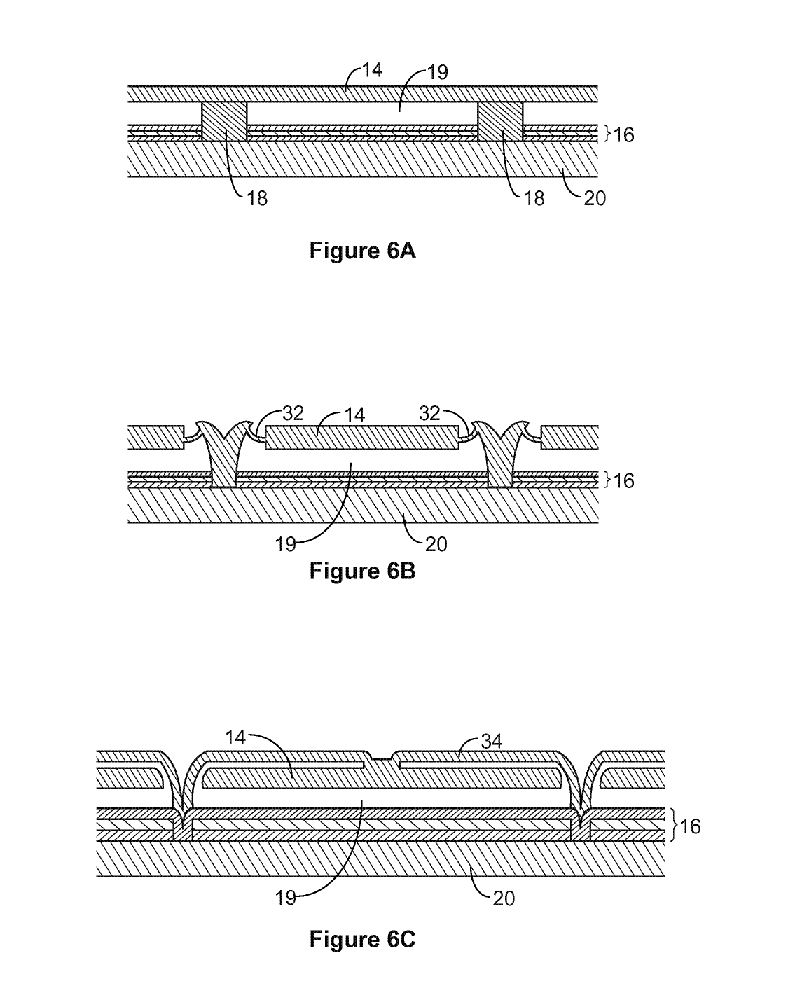

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

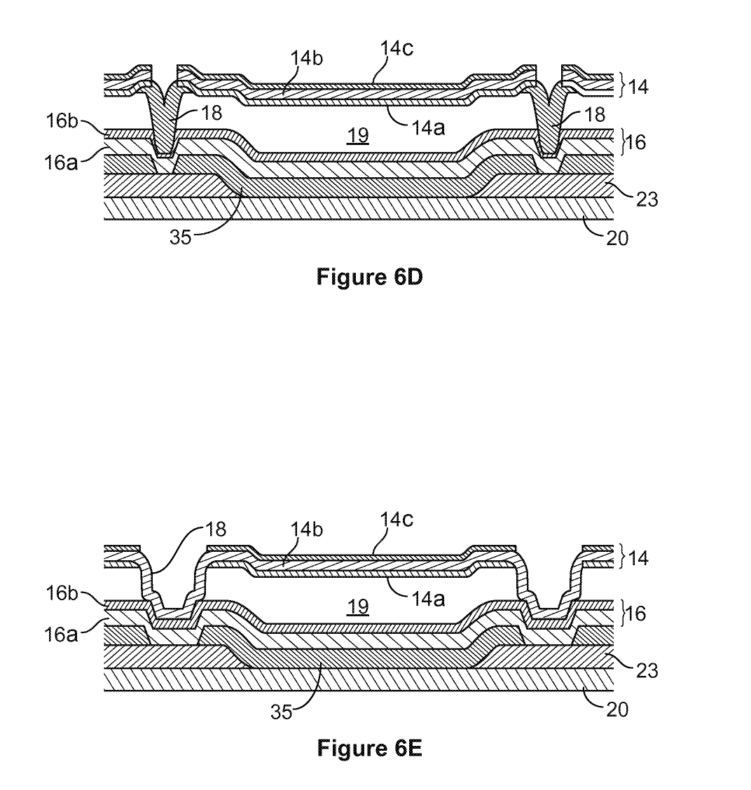

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

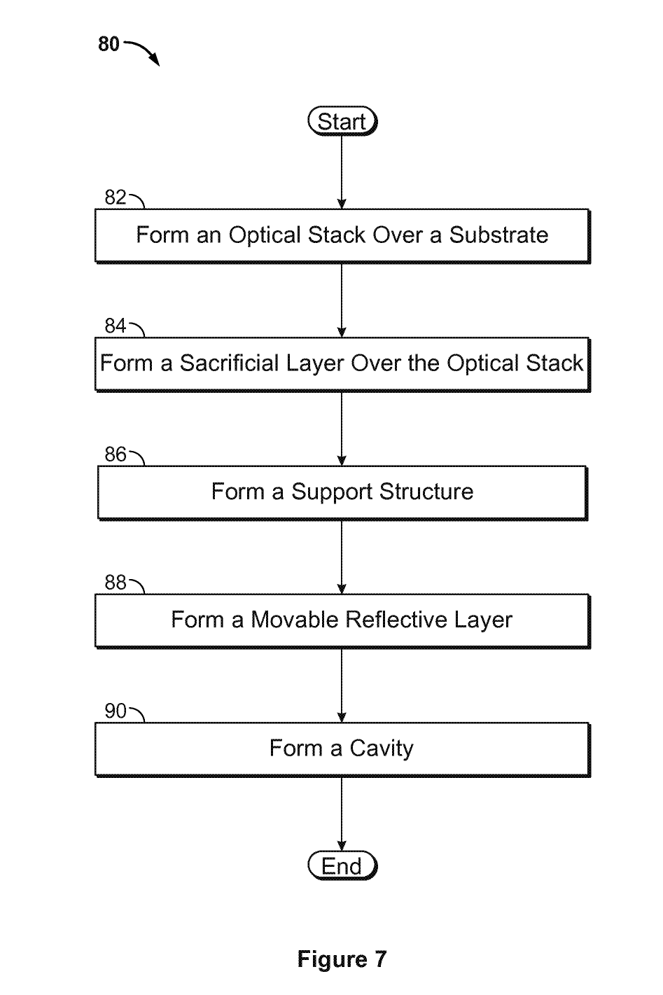

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CFO and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In some implementations, the optical absorber 16a is an order of magnitude (ten times or more) thinner than the movable reflective layer 14. In some implementations, optical absorber 16a is thinner than reflective sub-layer 14a.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

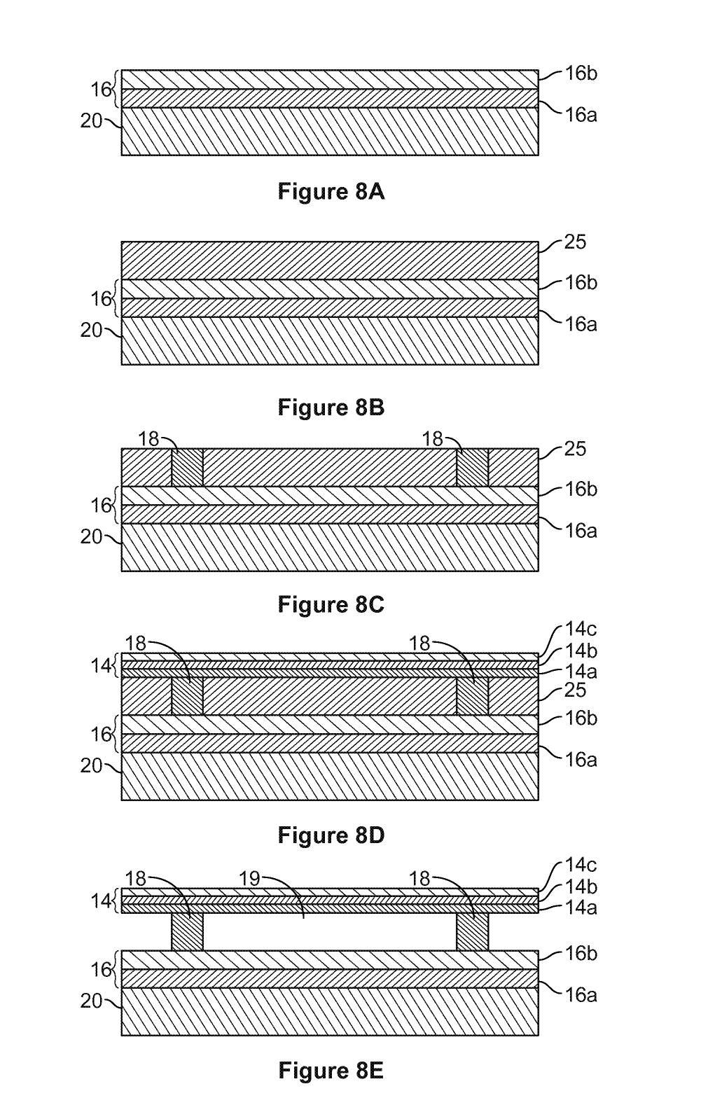

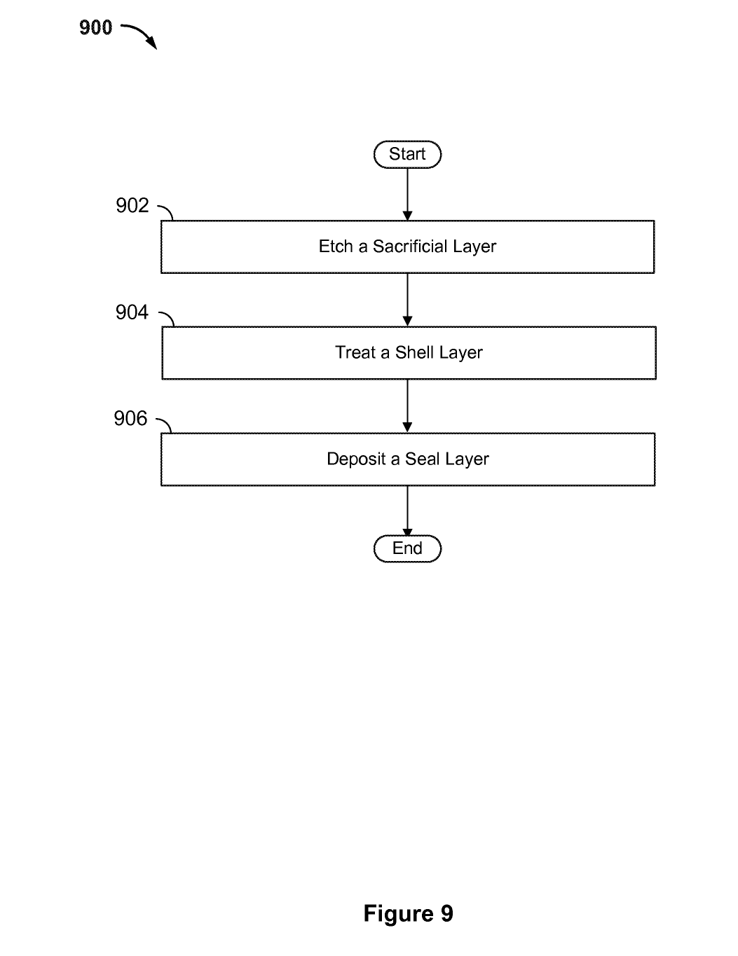

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6. The manufacture of an electromechanical systems device can also include other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as post 18, illustrated in FIGS. 1, 6 and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps including, for example, reflective layer (such as aluminum, aluminum alloy, or other reflective layer) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 illustrated in FIGS. 1, 6 and 8E. The cavity 19 may be formed by exposing the sacrificial material 25 (deposited at block 84) to an etchant. For example, an etchable sacrificial material such as Mo or a-Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

As noted above, an EMS device, including an IMOD, may be packaged to protect the EMS device from the environment and from operational hazards, such as mechanical shock. One packaging technique is a thin-film encapsulation process. To protect an EMS device from the environment, the thin-film encapsulation process may hermetically seal the EMS device. For example, the EMS device may be hermetically sealed between the substrate (and any associated layers) and a hermetic seal layer (and any associated layers).

A hermetic seal has the quality of being substantially airtight; i.e., a hermetic seal is substantially impervious to air, including water vapor and other gases in the air. Hermetic seals may serve to improve the performance of some EMS devices. For example, some EMS devices, including IMODs, include surfaces and/or parts that may come in and out of contact with one another. Adhesion of two separated layers of material to one another when the two layers come into contact with one another is an issue in some EMS devices. The phenomenon of two such layers adhering to one another in this manner is called stiction (i.e., static friction). Stiction in EMS devices may be exacerbated by water vapor in the air. Thus, hermetic seals that serve to protect an EMS device from water vapor may prolong the operational life of the EMS device.

For example, in the IMOD 12 shown in FIG. 1, when a voltage is applied to at least one of a selected row and column, the surface of the movable reflective layer 14 can deform, move toward, and contact the surface of the optical stack 16. Stiction can cause these two layers to remain in contact when the voltage is removed and a restoring force would be expected to return the movable reflective layer to the relaxed position. Stiction occurs when the sum of adhesive forces acting upon the movable reflective layer 14 in the IMOD 12 in the actuated position is greater than the sum of the restoring forces acting upon the movable reflective layer 14 to restore it to the relaxed position. Adhesive forces may include electrostatic forces, capillary forces, van der Waals forces, and/or hydrogen bonding forces. Restoring forces may include mechanical tension forces of the actuated movable reflective layer 14. Because adhesive forces become relatively stronger and restoring forces become relatively weaker with decreasing device dimensions, stiction becomes more of an issue with decreasing device size, such as in EMS devices including MEMS devices and NEMS devices.

Various implementations described herein involve processes of forming thin-film encapsulation layers. For example, in some implementations, a shell layer and a seal layer may be included in the thin-film encapsulation layers. The surface of the shell layer may be treated before forming a seal layer on the shell layer. The treatment may be performed, for example, after etching a sacrificial layer in the EMS device, after etching away sacrificial layers under the shell layer, or after patterning structural materials. After the treatment, the seal layer is formed on the shell layer. Implementations of the methods disclosed herein may result in a thin-film encapsulated EMS device in which the thin-film encapsulation hermetically seals the EMS device.

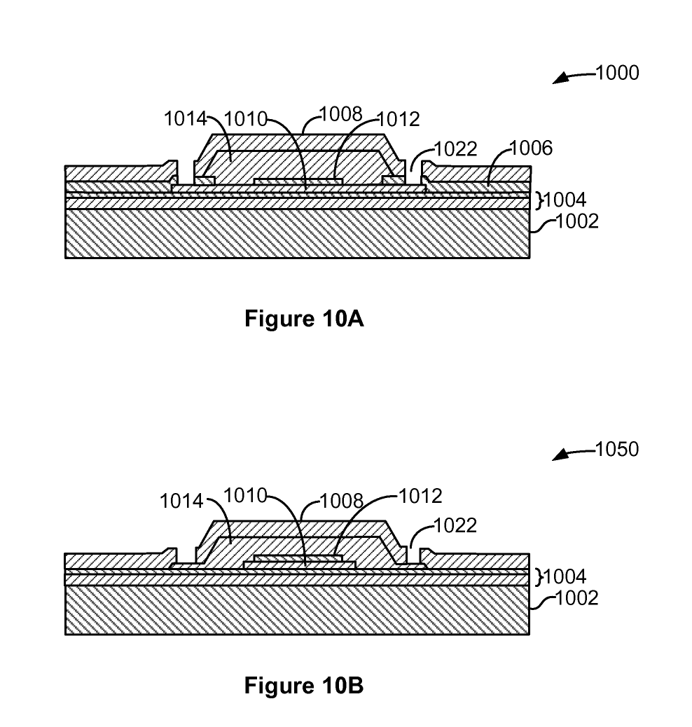

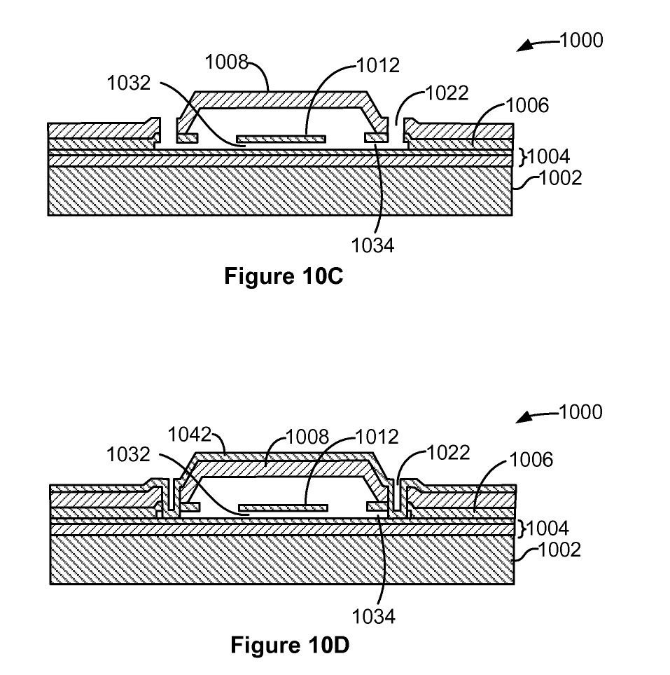

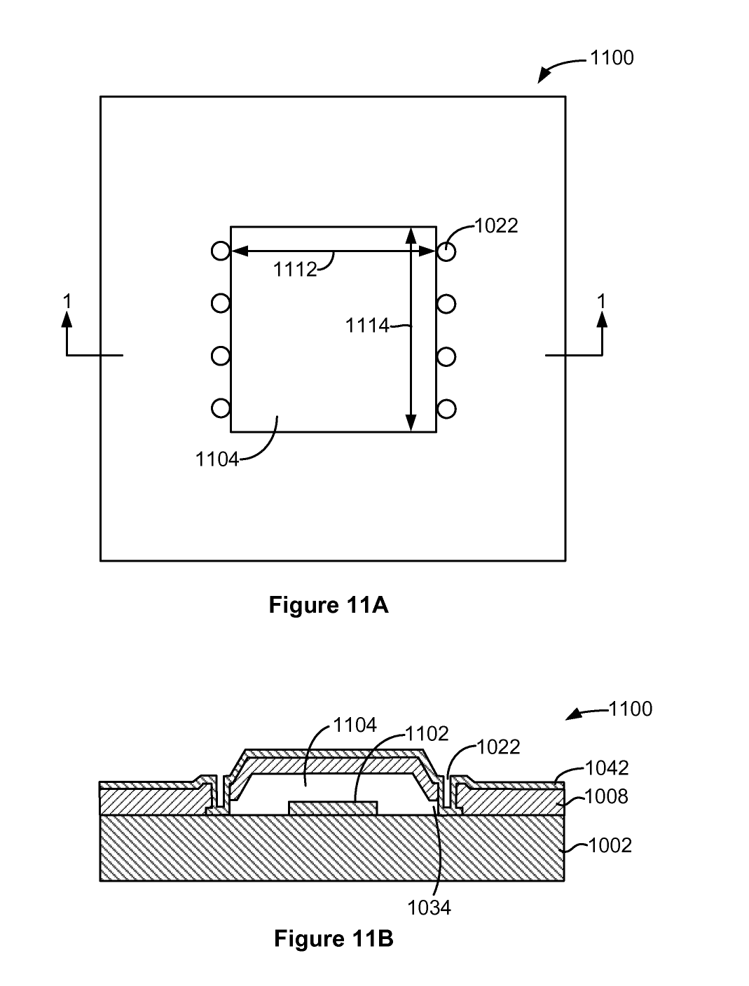

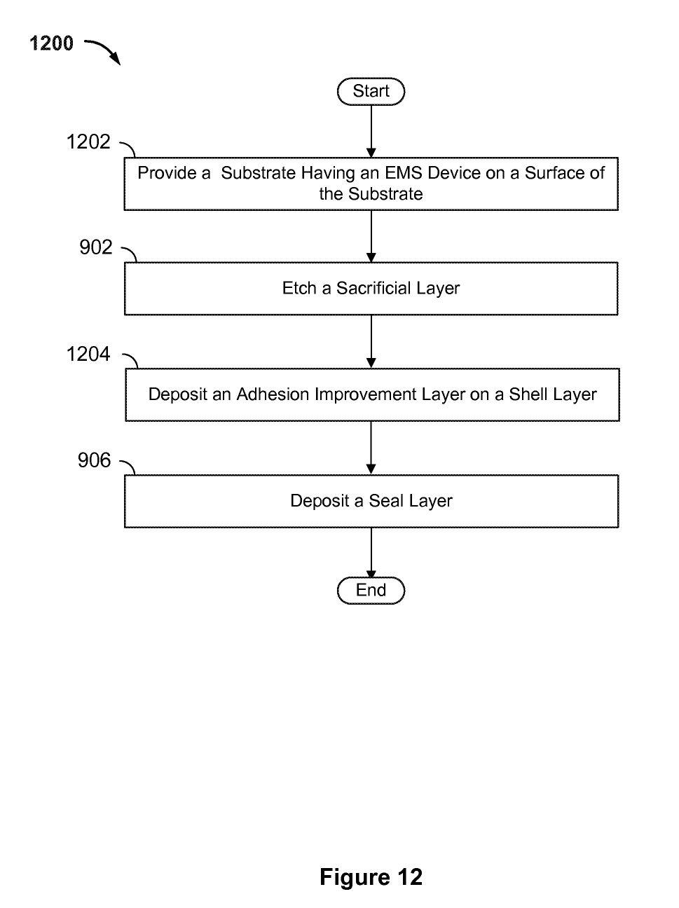

FIG. 9 shows an example of a flow diagram illustrating an implementation of a manufacturing process for an EMS assembly. FIGS. 10A-10D show examples of cross-sectional schematic illustrations of various stages in a method of fabricating an EMS assembly. FIGS. 11A and 11B show examples of schematic illustrations of an EMS assembly. The EMS assembly shown in FIGS. 11A and 11B is another example of a structure that may be produced by the process shown in FIG. 9. Another implementation of the manufacturing process shown in FIG. 9 is described in the example of a flow diagram shown in FIG. 12, in which some process operations included in FIG. 9 are omitted and further process operations are added.

The process 900 in FIG. 9 may be performed with a substrate having an EMS device on a surface of the substrate. In some implementations, the substrate includes a shell layer formed over the EMS device. The EMS device can include any of the EMS devices noted above.

FIG. 10A shows an example of a cross-sectional schematic illustration of an EMS assembly 1000 that the process 900 may be performed on. The EMS assembly 1000 includes an IMOD, but the process 900 is applicable to any number of EMS assemblies including different EMS devices. The illustrated EMS assembly 1000 includes a substrate 1002, a stationary electrode 1004, a post layer 1006, a shell layer 1008, a first sacrificial layer 1010, a movable electrode 1012, and a second sacrificial layer 1014. As illustrated, an etch hole 1022 through the shell layer 1008 exposes the first sacrificial layer 1010 without directly exposing the second sacrificial layer 1014.

FIG. 10B shows another example of a cross-sectional schematic illustration of an EMS assembly 1050 that the process 900 may be performed on. As illustrated in FIG. 10B, an etch hole 1022 through a shell layer 1008 exposes a second sacrificial layer 1014 without directly exposing a first sacrificial layer 1010. Further, as illustrated in FIG. 10B, in some implementations, the electrode 1012 may be self-supporting (with the electrode 1012 being able to bend down to contact the stationary electrode 1004 on the substrate 1002 in areas other than the shown the cross-sectional schematic illustration), and the EMS assembly 1050 may not include a post layer 1006.

The different components in the EMS assemblies 1000 and 1050 and their methods of fabrication are described further below. Additional details related to the components and their methods of fabrication are described in U.S. patent application Ser. No. 12/976,647, titled “METHOD OF FABRICATION AND RESULTANT ENCAPSULTED ELECTROMECHANICAL DEVICE.”

The substrate 1002 may be any number of different substrate materials, including transparent materials and non-transparent materials. In some implementations, the substrate is silicon, silicon-on-insulator (SOI), a glass (such as a display glass or a borosilicate glass), a flexible plastic, or a metal foil. In some implementations, the substrate on which an EMS device is fabricated has dimensions of a few microns to hundreds of microns. The stationary electrode 1004 may include an optical stack over the substrate 1002 and while it is illustrated as including two layers in FIGS. 10A-10D, it also may include three or more layers. The post layer 1006 may provide structural support for the movable electrode 1012 and/or the shell layer 1008. The supported sections of the movable electrode 1012 are not shown in the cross-sectional schematic illustration of FIG. 10A. For ease of illustration, the horizontal distance separating the movable electrode 1012 and the post layer 1006 has been exaggerated compared to the dimensions of a typical IMOD structure.

The first sacrificial layer 1010 may provide a support for the movable electrode 1012 during fabrication of the movable electrode 1012. In some implementations, the first sacrificial layer may be a polymer or a photoresist. In some other implementations, the first sacrificial layer may be a fluorine-etchable material, such as Mo, tungsten (W), or amorphous silicon (a-Si). The second sacrificial layer 1014 is on the movable electrode 1012, a portion of the post layer 1006, and a portion of the first sacrificial layer 1010. In some implementations, the second sacrificial layer 1014 provides a support for the shell layer 1008 during fabrication of the shell layer. The second sacrificial layer 1014 may be the same material as the first sacrificial layer 1010 or a different material from the first sacrificial layer 1010. In some implementations, the second sacrificial layer may be a polymer or a photoresist. In some other implementations, the second sacrificial layer may be a fluorine-etchable material, such as Mo, W, or a-Si.

The shell layer 1008 may be any number of different materials, including Al, aluminum oxide (Al₂O₃), aluminum nitride (AlN), silicon nitride (SiN), SiO₂, SiON, polysilicon (poly-Si), silicon (Si), benzocyclobutene (BCB), acrylic, polyimide, other similar materials, and combinations thereof. In some implementations, the shell layer may at least partially enclose the EMS device. In some other implementations, the shell layer may be formed over the EMS device. In some implementations, the thickness of the shell layer may be sufficient to mechanically isolate the EMS device. In some implementations, the thickness of the shell layer may be about 100 nanometers to 20 microns, or about 1 micron to 3 microns.

In some implementations, the shell layer may be substantially nonporous. When the shell layer is substantially nonporous, liquids and/or gases generally cannot pass through the shell layer. For example, when the shell layer is substantially nonporous, the sacrificial layer may not be removed by the diffusion of etchants or other chemicals through the shell layer.

In some implementations, the shell layer includes an etch hole 1022. The etch hole 1022 may expose the first sacrificial layer 1010 without directly exposing the second sacrificial layer 1014. The etch hole allows for the removal of the first sacrificial layer and the second sacrificial layer, in some implementations. In some implementations, the etch hole may have a circular, annular, or other geometry. In some implementations, the etch hole may have a diameter greater than about 1 micron. In some implementations, the etch hole may have diameter of about 2 microns to 10 microns.

The process 900 in FIG. 9 begins at block 902, with etching a sacrificial layer. In some implementations, the sacrificial layer may be etched through etch holes in the shell layer. In some implementations, etching the sacrificial layer removes the sacrificial layer. In some implementations, a sacrificial layer may be etched from an EMS device to remove the sacrificial layer from the EMS device. In some other implementations, a sacrificial layer on which the shell layer is formed is etched. For example, for the EMS device 1000 shown in FIG. 10A, both the first sacrificial layer 1010 and the second sacrificial layer 1014 may be etched, but in some other implementations, only the second sacrificial layer 1014 is etched. The process used to remove the sacrificial layers depends on the materials of the sacrificial layers. For example, if the first sacrificial layer 1010 is Mo, W, or a-Si, XeF₂ may be used to etch the first sacrificial layer by exposing the first sacrificial layer to XeF₂. If the first sacrificial layer 1010 is a polymer or a photoresist, an appropriate solvent, an oxygen plasma, an ashing process, or other technique may be used to etch the first sacrificial layer. If the second sacrificial layer 1014 is the same material as the first sacrificial layer 1010 or is etched by the same etchant that etches the first sacrificial layer, the second sacrificial layer may be etched at the same time that the first sacrificial layer is etched. If the second sacrificial layer 1014 is a different material than the first sacrificial layer 1010 or is etched by a different etchant than an etchant that etches the first sacrificial layer, the second sacrificial layer may be etched in another process operation.

In some implementations, etching a sacrificial layer forms a release passage connected to the etch hole (such as release passage 1034 in FIGS. 10C and 10D). The release passage may be a volume that a sacrificial layer occupies before the sacrificial layer is removed by etching. In some implementations, the dimensions of the release passage may facilitate subsequent sealing of the EMS device by the seal layer. For example, the release passage may be long and narrow. In some implementations, the release passage may have a horizontal length that is substantially parallel to the surface of the substrate. In some implementations, the release passage may have a horizontal length that is about 2 to 20 times the vertical height of the release passage. Having a length of the release passage that is about 2 to 20 times the vertical height of the release passage may reduce the chance that a subsequently deposited sealing layer will deposit onto and possibly interfere with parts of an EMS device, such as, for example, the movable electrode 1012 or the stationary electrode 1004 of the EMS device 1000 shown in FIG. 10A. In some implementations, the release passage may have a height of less than about 1 micron and a width of greater than about 1 micron. In some other implementations, the release passage may have a height of about 0.1 microns to 0.75 microns and a width of about 2 microns to 10 microns. For example, the release passage may have a height of about 0.2 microns and a width of about 5 microns.

FIG. 10C shows an example of a cross-sectional schematic illustration of the EMS assembly 1000 at this point (that is, up through the block 902) in the process 900. Removing the first sacrificial layer 1010 from the EMS assembly 1000 forms a gap 1032 between the movable electrode 1012 and the stationary electrode 1004. As noted above, the movable electrode 1012 may be supported by the post layer 1006, but the supporting sections of the post layer 1006 are not shown in FIG. 10C. In the implementation illustrated in FIG. 10C, an etchant first forms a release passage 1034 by etching portions of the sacrificial layer 1010 connected to the etch hole 1022 before subsequently reaching portions of the sacrificial layer 1010 underneath the movable electrode 1012. The release passage 1034 may be positioned between the post layer 1006 and the stationary electrode 1004.

At block 904 of the process 900, the shell layer is treated. The shell layer may be treated by many different techniques. In some implementations, the treatment includes depositing an adhesion improvement layer on the shell layer, for example at least a monolayer of material. In some implementations, the treatment includes thermally treating the shell layer at an elevated temperature, exposing the shell layer to ultraviolet light, exposing the shell layer to a chemical reactant, or forming a self-assembled monolayer (SAM) on the shell layer. In some implementations, the treatment includes treating an area of the shell layer adjacent to the etch hole and a portion of the sidewall of the etch hole.

In some implementations, a monolayer of material or a layer of material may be deposited by an atomic layer deposition (ALD) process. In some implementations, such a layer can serve as a treatment for a shell layer that improves the adhesion of subsequently deposited layers. ALD is a thin-film deposition technique performed with one or more chemical reactants, also referred to as precursors. ALD processes can be based on sequential, self-limiting surface reactions. The precursors can be sequentially admitted to a reaction chamber in a gaseous state where they contact a surface, such as a shell layer surface, that is being coated with a material. For example, a first precursor may be adsorbed onto the surface when it is admitted to a reaction chamber. Then, the first precursor reacts with a second precursor at the surface when the second precursor is admitted to the reaction chamber. By repeatedly exposing a surface to alternating sequential pulses of the precursors, a thin film of material is deposited. ALD processes also include processes in which a surface is exposed to sequential pulses of a single precursor, which deposits a thin film of material on the surface. ALD processes generally form a conformal layer, i.e., a layer that follows the contours of the underlying surface. In some implementations, one ALD process cycle or multiple ALD process cycles are performed to treat the shell layer. For example, in some implementations, about 40 ALD process cycles may be performed.

In some implementations, the material deposited by an ALD process is Al₂O₃ also referred to as alumina. In some implementations, operations for depositing Al₂O₃ by an ALD process include contacting a surface with a pulse of an aluminum precursor gas followed by a pulse of an oxygen precursor gas. For example, in some implementations, Al₂O₃ is deposited by an ALD process using trimethyl aluminum (TMA) as an aluminum precursor gas and at least one of water (H₂O) or ozone (O₃) as an oxygen precursor gas. Other suitable aluminum precursor gases include tri-isobutyl aluminum (TIBAL), tri-ethyl aluminum (TEA), tri-ethyl/methyl aluminum (TEA/TMA), dimethylaluminum hydride (DMAH), and the like.

In some implementations, a treatment of the shell layer may cover residues on the shell layer. For example, when a sacrificial layer is removed using an etchant, such as XeF₂, residues from the etchant or from the chemical reaction between the sacrificial layer and the etchant may remain on the shell layer. Depositing at least a monolayer of material or a layer of material on the shell layer may cover such residues and improve the bond between the shell layer and the seal layer. Covering the residues also may result in a seal layer that is not contaminated or otherwise affected by any existing residues on the shell layer, which may improve the performance of the seal layer.

In some other implementations, treating the shell layer may chemically alter and/or remove any residues on the shell layer. For example, exposing the shell layer to a chemical reactant or to the precursors used in an ALD process may alter the composition of any residues on the shell layer or remove any residues on the shell layer. As another example, treating the shell layer at an elevated temperature or exposing the shell layer to ultraviolet (UV) light may oxidize or otherwise chemically alter any residues on the shell layer. Wavelengths of ultraviolet light may range from about 10 to 400 nanometers, for example.

Returning to FIG. 9, at block 906, a seal layer is deposited on the shell layer. In some implementations, the seal layer hermetically seals the EMS device. For example, in some implementations, the seal layer forms a hermetic seal, i.e., a seal substantially impervious to air or gas. A seal layer that hermetically seals the EMS device from the environment may improve the operational life of the EMS device. In some implementations, the seal layer may be a conformal layer or a thin film. In some implementations, the seal layer may cover the shell layer. In some implementations, the seal layer may block a release passage connected to the etch hole in the shell layer. The seal layer may be formed with deposition processes including PVD processes, chemical vapor deposition (CVD) processes, PECVD processes, spin-on glass (SOG) processes, and ALD processes.

The seal layer may include any number of different materials, including a metal, or SiON, SiO₂, Al₂O₃, and other dielectric materials. The seal layer also may be a multilayered material. In some implementations, the seal layer is a multilayered material including a layer of Al₂O₃ on a layer of SiON. For example, a layer of SiON may be deposited on the shell layer, and a layer of Al₂O₃ may be deposited on the SiON layer, forming a SiON/Al₂O₃ seal layer. In some implementations, a SiON/Al₂O₃ seal layer includes a SiON layer having a thickness between about 0.5 microns to 2.5 microns and an Al₂O₃ layer having a thickness of about 30 nanometers to 90 nanometers. In some implementations, a SiON/Al₂O₃ seal layer includes a SiON layer having a thickness of about 1.5 microns and an Al₂O₃ layer having a thickness of about 60 nanometers. In some implementations, a SiON layer may be formed with a PECVD process. In some implementations, an Al₂O₃ layer may be formed with about 200 to 600 ALD process cycles, or about 400 ALD process cycles. In some other implementations, the seal layer is a multilayered material including a layer of Al₂O₃ between two layers of SiON, forming a SiON/Al₂O₃/SiON seal layer. In some implementations, the SiON layers of a SiON/Al₂O₃/SiON seal layer may each be about 0.5 microns to 2.5 microns thick and the Al₂O₃ layer may be about 30 nanometers to 90 nanometers thick. In some implementations, the SiON layers may each be about 1.5 microns thick and the Al₂O₃ layer may be about 60 nanometers thick.

FIG. 10D shows an example of a cross-sectional schematic illustration of the EMS assembly 1000 at this point (that is, up through the block 906) in the process 900. The EMS assembly 1000 includes the substrate 1002, the stationary electrode 1004, the post layer 1006, the shell layer 1008, the movable electrode 1012, and the gap 1032 between the movable electrode 1012 and the stationary electrode 1004. The shell layer 1008 includes the etch hole 1022 and the release passage 1034 is connected to the etch hole. A seal layer 1042 hermetically seals the etch hole 1022 in the shell layer 1008 by blocking the opening of a release passage 1034 connected to the etch hole.

FIGS. 11A and 11B show examples of schematic illustrations of an EMS assembly. The EMS assembly 1100 shown in FIGS. 11A and 11B is another example of a structure that may be produced by the process 900. FIG. 11A shows an example of a top-down view of the EMS assembly 1100. FIG. 11B shown a cross-sectional schematic view of the EMS assembly 1100 though line 1-1 of FIG. 11A. The EMS assembly 1100 shown in FIG. 11B is similar to the EMS assembly 1000 shown in FIG. 10D.

The EMS assembly 1100 shown in FIG. 11B includes a substrate 1002, a shell layer 1008, a seal layer 1042, and an EMS device 1102. The EMS device 1102 may be formed on the substrate 1002. The EMS device 1102 can be any of a number of different EMS devices. The EMS device 1102 is encapsulated within an open volume 1104 of the EMS assembly 1100.

The shell layer 1008 at least partially encloses the EMS device 1102 between the shell layer 1008 and the substrate 1002. The shell layer 1008 also includes an etch hole 1022. The seal layer 1042 hermetically seals the etch hole 1022 in the shell layer 1008 by blocking an opening of a release passage 1034 connected to the etch hole. In some implementations, the shell layer 1008 is treated according to a method disclosed herein before formation of the seal layer 1042 to improve the hermetic properties of the seal layer.

The top-down view of the EMS assembly 1100 shown in FIG. 11A includes an outline of the open volume 1104. A length 1112 and a width 1114 of the open volume 1104 each may be about 20 microns to 150 microns. The EMS assembly 1100 includes 8 etch holes 1022. The number etch holes may be fewer or greater, depending on the size of the EMS assembly and the etch process used to etch the sacrificial layer.

FIG. 12 shows an example of a flow diagram illustrating a manufacturing process for an EMS assembly. The method 1200 shown in FIG. 12 is similar to the method 900 shown in FIG. 9, with some process operations shown in FIG. 9 being condensed and/or omitted and some process operations being added.

At block 1202 of the process 1200, a substrate having an EMS device on the surface of the substrate is provided. A shell layer at least partially encloses the EMS device. The shell layer also is substantially nonporous, and includes an etch hole. Various substrates, EMS devices, and shell layers are described above.

At block 902, a sacrificial layer is etched. The sacrificial layer is etched from the substrate through the etch hole. Etching the sacrificial layer can form a release passage. In some implementations, the release passage has a height of less than about 1 micron and a width of greater than about 1 micron. Block 902 is described further, above.

At block 1204, after etching the sacrificial layer, an adhesion improvement layer is deposited on the shell layer. The adhesion improvement layer can improve the adhesion of the subsequently deposited seal layer onto the shell layer after the sacrificial material is etched from beneath the shell layer. In some implementations, the adhesion improvement layer includes at least a monolayer of aluminum oxide that is deposited on the shell layer with an ALD process. The process operation at block 1204 is a treatment of the shell layer; i.e., the process operation at block 1204 is a specific implementation of the process operation at block 904 of the manufacturing process 900, described above. Process operations in an ALD process are also described above.

At block 906, a seal layer is deposited on the shell layer. The seal layer blocks the release passage and hermetically seals the electromechanical systems device. Block 906 is described further, above.

An experiment was performed on the thin-film encapsulation materials produced using the processes disclosed here. In “process 1”, a seal layer was deposited on a shell layer of an EMS assembly. The seal layer included an about 1.5 micron layer of SiON, an about 60 nanometer layer of Al₂O₃ on the SiON layer, and an about 1.5 micron layer of SiON on the Al₂O₃ layer. The Al₂O₃ layer was deposited by an ALD process. In “process 2”, the shell layer was treated by exposing the shell layer to 35 ALD process cycles for depositing Al₂O₃. The 35 ALD process cycles deposited an about 4 nanometer thick layer of Al₂O₃. Then, a seal layer similar to the seal layer of “process 1” was deposited onto the treated shell layer. Both the “process 1” and the “process 2” EMS assemblies were then exposed to an environment of about 85° C. and about 85% relative humidity.

The hermetic properties of the seal layer of the “process 1” EMS assembly failed in the environment of about 85° C. and about 85% relative humidity before 50 hours of exposure had elapsed. In contrast, the seal layer of the “process 2” EMS assembly maintained its hermetic properties for 300 hours in the environment of about 85° C. and about 85% relative humidity, but failed before 500 hours of exposure had elapsed. Some seal layers formed with treatment processes similar to the “process 2” treatment process, however, have maintained their hermetic properties for over 2,500 hours in an environment of about 85° C. and about 85% relative humidity.

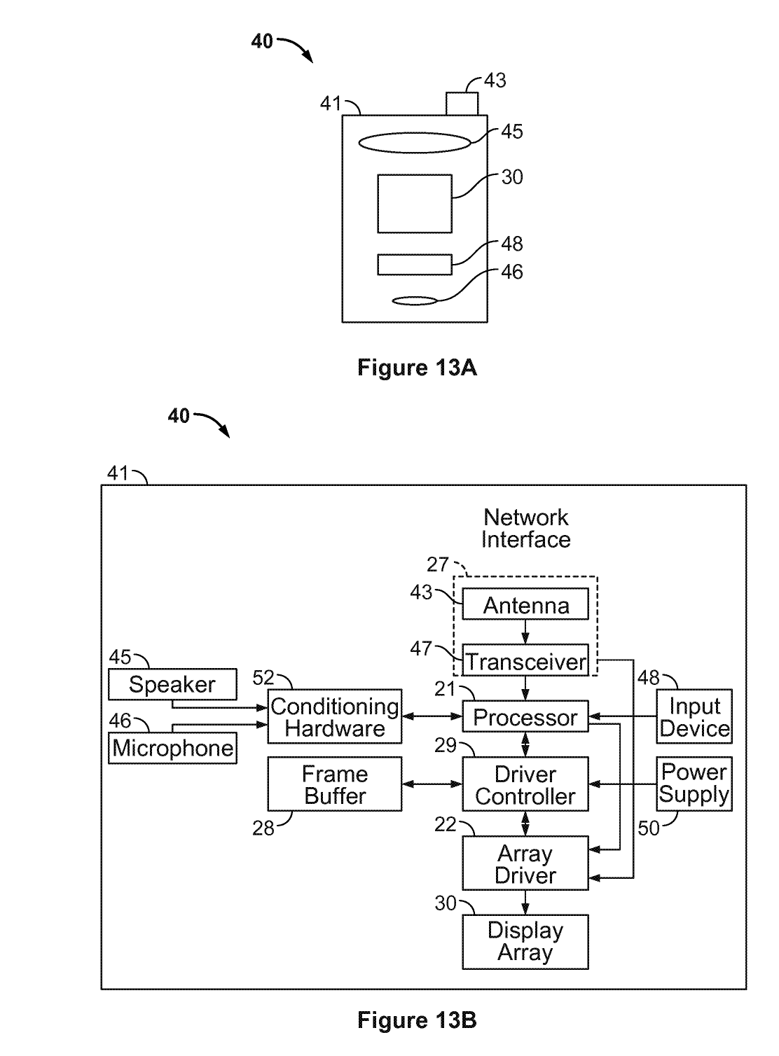

FIGS. 13A and 13B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus. If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A method of sealing an electromechanical systems device comprising:
etching a sacrificial layer through etch holes in a shell layer formed over the electromechanical systems device, the etch holes having a diameter greater than about 1 micron and the sacrificial layer being formed between a surface of a substrate and the shell layer;
treating the shell layer after etching the sacrificial layer; and
depositing a seal layer on the shell layer, wherein the seal layer hermetically seals the electromechanical systems device.

2. The method as recited in claim 1, wherein the sacrificial layer includes at least one of molybdenum, tungsten, or amorphous silicon.

3. The method as recited in claim 2, wherein etching the sacrificial layer is performed by exposing the sacrificial layer to xenon difluoride.

4. The method as recited in claim 1, wherein an etch hole has a diameter of about 2 microns to 10 microns.

5. The method as recited in claim 1, wherein etching the sacrificial layer forms a release passage connected to an etch hole.

6. The method as recited in claim 5, wherein depositing the seal layer blocks the release passage.

7. The method as recited in claim 5, wherein the release passage has a height of less than about 1 micron and a width of greater than about 1 micron.

8. The method as recited in claim 5, wherein the release passage has a height of about 0.1 microns to 0.75 microns and a width of about 2 microns to 10 microns.

9. The method as recited in claim 1, wherein the shell layer is substantially nonporous.

10. The method as recited in claim 1, wherein treating the shell layer includes treating an area of the shell layer adjacent to an etch hole in the shell layer and a portion of a sidewall of the etch hole.

11. The method as recited in claim 1, wherein treating the shell layer includes depositing at least a monolayer of material on the shell layer with an atomic layer deposition process.

12. The method as recited in claim 11, wherein the material deposited includes aluminum oxide.

13. The method as recited in claim 1, wherein depositing the seal layer includes depositing a layer of silicon oxynitride by a plasma enhanced chemical vapor deposition process.

14. The method as recited in claim 13, wherein depositing the seal layer further includes depositing a layer of aluminum oxide by an atomic layer deposition process on the layer of silicon oxynitride.

15. A method of sealing an electromechanical systems device comprising:
providing a substrate having the electromechanical systems device on a surface of the substrate and a shell layer at least partially enclosing the electromechanical systems device, wherein the shell layer is substantially nonporous, and wherein the shell layer includes an etch hole;
etching a sacrificial layer from the substrate though the etch hole, wherein etching the sacrificial layer forms a release passage, the release passage having a height of less than about 1 micron and a width of greater than about 1 micron;
after etching the sacrificial layer, depositing an adhesion improvement layer on the shell layer; and
depositing a seal layer on the shell layer, wherein the seal layer blocks the release passage and hermetically seals the electromechanical systems device.

16. The method as recited in claim 15, wherein the adhesion improvement layer includes at least a monolayer of aluminum oxide.

17. The method as recited in claim 15, wherein the sacrificial layer includes at least one of molybdenum, tungsten, or amorphous silicon.

18. The method as recited in claim 17, wherein etching the sacrificial layer is performed by exposing the sacrificial layer to xenon difluoride.

19. The method as recited in claim 15, wherein depositing the seal layer includes depositing a layer of silicon oxynitride by a plasma enhanced chemical vapor deposition process followed by depositing a layer of aluminum oxide by an atomic layer deposition process.

20. An apparatus comprising:
an electromechanical systems device formed on a substrate;
a supporting means, the supporting means including a sealed etch hole; and
a sealing means for hermetically sealing the electromechanical systems device, the sealing means being over the supporting means, the sealing means sealing the etch hole with a portion of the sealing means blocking an opening of a release passage connected to the etch hole.

21. The apparatus of claim 20, wherein the supporting means is a shell layer and the sealing means is a seal layer.

22. An apparatus comprising:
an electromechanical systems device formed on a substrate;
a shell layer at least partially enclosing the electromechanical systems device between the shell layer and the substrate, the shell layer including a sealed etch hole; and
a seal layer over the shell layer, the seal layer hermetically sealing the etch hole in the shell layer with a portion of the seal layer blocking an opening of a release passage connected to the etch hole.

23. The apparatus as recited in claim 22, wherein the seal layer includes a layer of silicon oxynitride and a layer of aluminum oxide overlying the layer of silicon oxynitride.

24. The apparatus as recited in claim 22, wherein the release passage has a height of less than about 1 micron and a width of greater than about 1 micron.

25. The apparatus as recited in claim 22, further comprising:
a display including one or more of the electromechanical systems devices in an array;
a processor that is configured to communicate with the display, the processor being configured to process image data; and
a memory device that is configured to communicate with the processor.

26. The apparatus as recited in claim 25, further comprising:
a driver circuit configured to send at least one signal to the display; and
a controller configured to send at least a portion of the image data to the driver circuit.

27. The apparatus as recited in claim 25, further comprising:
an image source module configured to send the image data to the processor.

28. The apparatus as recited in claim 27, wherein the image source module includes at least one of a receiver, transceiver, and transmitter.

29. The apparatus as recited in claim 25, further comprising:
an input device configured to receive input data and to communicate the input data to the processor.
